(19) United States
(12) Patent Application Publication
(10) Pub. No.: US 2021/0202344 A1
(43) Pub. Date: Jul. 1, 2021

(54) SEMICONDUCTOR DEVICE AND MANUFACTURING METHOD THEREOF

(71) Applicant: Industrial Technology Research Institute, Hsin-Chu (TW)

(72) Inventors: CHIH-CHIANG WU, Keelung City (TW); CHENG-HAN HO, Tainan City (TW); SHIH-KAI HSIEH, Taoyuan City (TW); LI-SONG LIN, Nantou County (TW)

(21) Appl. No.: 16/727,119

(22) Filed: Dec. 26, 2019

(51) Int. Cl. H01L 23/367; H01L 23/498; H01L 23/373; H01L 23/15; H01L 21/48

(52) U.S. Cl. CPC H01L 23/3675; H01L 23/49811; H01L 23/3736; H01L 23/15; H01L 23/3731; H01L 21/4853; H01L 21/4882; H01L 23/49838; H01L 21/4875

(57) ABSTRACT

A semiconductor device includes an insulating thermal substrate, a metal wiring layer and a heat-dissipation component. The metal wiring layer includes a plurality of engaging structures. The plurality of engaging structures is disposed between the insulating thermal substrate and the heat-dissipation component, and the heat-dissipation component applies solder structures to connect the metal wiring layer by having the solder structures to wrap partly the plurality of engaging structures. In addition, a method for fabricating the same semiconductor device is also provided.

### TECHNICAL FIELD

The present disclosure relates in general to a semiconductor device and a method for manufacturing the semiconductor device.

### BACKGROUND

Currently, one of market trends in power modules goes to a product demonstrating integrally high power, thin and high density. In addition, thermal stress and fatigue life shall meet specific requirements. In high-power power modules, superior power output can be attained through connecting in parallel with a least-power transistor.

In general, a typical power module is formed by having a power transistor mounted at one side of a ceramic substrate and a metal heat-dissipation component is mounted at another side of the same ceramic substrate. In this structure of the power module, the ceramic substrate itself has a pretty high thermal conductivity and a big current load capacity. Thus, heat generated at the transistor can be easily conducted through the ceramic substrate, and then conducted to the metal heat-dissipation component. In other words, the power module can have the ceramic substrate to serve as a medium for heat conduction, i.e., for heat dissipation.

Nevertheless, in the power module, since a big difference in thermal expansion exists between the ceramic substrate and the metal heat-dissipation component, thus cracks occurring at junction materials (such as solder) between the ceramic substrate and the metal heat-dissipation component are highly possible, and such defects would change the heat-transfer path. Namely, performance in dissipating heat at the transistor would be a problem. Hence, an improved semiconductor device and an associated method for manufacturing the same semiconductor device to resolve the aforesaid shortcomings are definitely urgent and welcome to the skill in the art.

### SUMMARY

An object of the present disclosure is to provide a semiconductor device and a manufacturing method thereof that can improve the heat-dissipation area and the heat-transfer path at the solder structures connecting the insulating thermal substrate and the heat-dissipation component.

In one embodiment of this disclosure, a semiconductor device includes an insulating thermal substrate, a metal wiring layer and a heat-dissipation component. The metal wiring layer includes a plurality of engaging structures. The plurality of engaging structures is disposed between the insulating thermal substrate and the heat-dissipation component, and the heat-dissipation component applies solder structures to connect the metal wiring layer by having the solder structures to wrap partly the plurality of engaging structures.

In another embodiment of this disclosure, a method for manufacturing a semiconductor device includes a step of forming a metal wiring layer having a plurality of engaging structures on an insulating thermal substrate, wherein each of the plurality of engaging structures is protruded from the insulating thermal substrate; a step of forming solder structures on a heat-dissipation component, wherein the solder structures have a plurality of protrusive columns; a step of aligning the plurality of engaging structures of the metal wiring layer with the plurality of corresponding protrusive columns of the solder structures, wherein an interval exists between any two neighboring of the plurality of protrusive columns and corresponding one of the plurality of engaging structures; and, a step of hot pressing the insulating thermal substrate and the heat-dissipation component to have the solder structures to wrap partly the plurality of engaging structures, so that the heat-dissipation component engages the metal wiring layer, wherein, after hot pressing, each of the plurality of protrusive columns deforms sideward into the interval.

As stated above, in the semiconductor device and the method for manufacturing the same semiconductor device of this disclosure, while in hot-depressing the heat-dissipation component and the insulating thermal substrate, with the cross-section design upon the engaging structures of the metal wiring layer and the solder structures, the molten solder structures can wrap the corresponding engaging structures without inducing residual stress in between, thus both the heat-dissipation area and heat-conduction pathways through the solder structures between the insulating thermal substrate and the heat-dissipation component can be substantially increased.

Further, though a big difference exists in the expansion coefficient between the insulating thermal substrate and the heat-dissipation component, yet the solder structures of this disclosure adopting the sintering silver with high thermal conductivity can promote effectively the heat conduction, and also crack resistance at the solder structures can be substantially enhanced. Therefore, solder cracking caused by the difference in thermal conductivity between the insulating thermal substrate and the heat-dissipation component can be avoided.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1A is a schematic view of an embodiment of the semiconductor device in accordance with this disclosure;

FIG. 1B is a schematic view of another embodiment of the semiconductor device in accordance with this disclosure;

FIG. 2 is a schematic view showing a pre-engaged state of the solder structures and the metal wiring layer in accordance with this disclosure;

FIG. 3 is a schematic view showing an engaged state of the solder structures and the metal wiring layer in accordance with this disclosure;

FIG. 4A is a schematic view of an exemplary example including a plurality of metal wiring layers in accordance with this disclosure;

FIG. 4B is a schematic view of an embodiment that corner angles of the corresponding engaging structures of FIG. 4A have been applied with fillet processing;

FIG. 4C is a schematic view of another exemplary example including a plurality of metal wiring layers in accordance with this disclosure;

FIG. 4D is a schematic view of a further exemplary example including a plurality of metal wiring layers in accordance with this disclosure;

FIG. 4E is a schematic view of an embodiment that corner angles of the corresponding engaging structures of FIG. 4D have been applied with fillet processing;

FIG. 4F is a schematic view of one more exemplary example including a plurality of metal wiring layers in accordance with this disclosure;

FIG. 4G is a schematic view of an embodiment that corner angles of the corresponding engaging structures of FIG. 4F have been applied with fillet processing; and

FIG. 5 is a flowchart of an embodiment of the method for manufacturing a semiconductor device in accordance with this disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

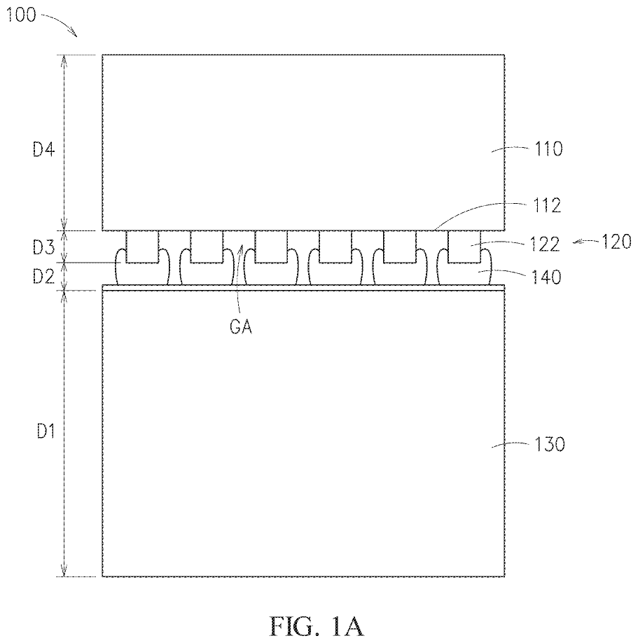

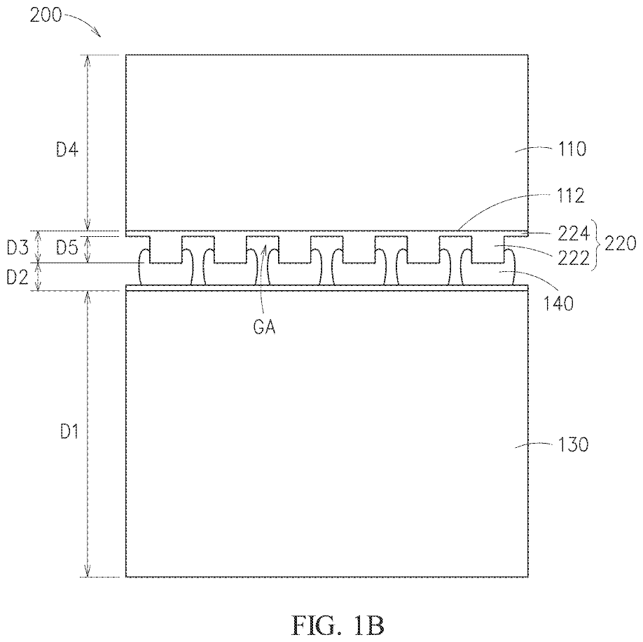

Referring to FIG. 1A, a schematic view of an embodiment of the semiconductor device in accordance with this disclosure is shown. In this embodiment, the semiconductor device 100 includes an insulating thermal substrate 110, a metal wiring layer 120 and a heat-dissipation component 130. The insulating thermal substrate 110 can be a ceramic substrate containing aluminum nitride, aluminum oxide, beryllium oxide, silicon nitride, silicon carbide or the like ceramic material. The metal wiring layer 120 includes a plurality of engaging structures 122, and each of the engaging structures 122 is protruded out from a surface 112 of the insulating thermal substrate 110. In this embodiment, the metal wiring layer 120 can be made of a metallic material such as copper. To form a copper wiring layer 120, an etching process can be applied to form simultaneously a plurality of protrusive engaging structures 122. Nevertheless, according to this disclosure, the method for manufacturing the engaging structures 122 is not limited to the aforesaid etching process.

In this embodiment, a plurality of solder structures 140 is furnished to the heat-dissipation component 130 for engaging the metal wiring layer 120. In this disclosure, the heat-dissipation component 130, as a heat sink for dissipating heat generated by the semiconductor device, can be made of a metallic material such as copper, and each of the solder structures 140 can be made of a sintering silver. The solder structures 140 are used for grasping corresponding one of the engaging structures 122, all made of the same material in the metal wiring layer 120. Thereupon, with the metal wiring layer 120 integrated with the heat-dissipation component 130, the insulating thermal substrate 110 and the heat-dissipation component 130 can be connected together. In other words, with each of the engaging structures 122 being dipped and thus engaging the corresponding solder structures 140, the solder structures 140 (deformable above a specific temperature) can be squeezed in a concave manner to surround each of the engaging structures 122.

Under such an arrangement, in a hot-pressing process upon the heat-dissipation component 130 and the insulating thermal substrate 110, the engaging structures 122 protruding individually from the surface 112 of the insulating thermal substrate 110 are integrated and coordinated with the specific geometric shape of solder structures 140 to be relevantly formed. As such, those specific geometric shape of solder structures 140 and intervals serve as stress-releasing sinks for the piercing engaging structures 122. Each of the solder structures 140 can be deformed locally/partly to surround or wrap substantially the corresponding engaging structure 122, such that the heat-dissipation interfaces and thermal conductive pathways between the insulating thermal substrate 110 and the heat-dissipation component 130 can be enhanced and assured.

Further, since a big difference in expansion coefficient exists between the insulating thermal substrate 110 (for example, a ceramic circuit board) and the heat-dissipation component 130, the solder portion therebetween would be too vulnerable for cracking. The cracks will block the heat dissipation paths so that the heat generated by the power transistor will not well dissipate. However, in this embodiment, since the sintering silver has a high thermal conductivity, thus the solder structures 140 made of the sintering silver can definitely has a satisfied thermal conductivity. Hence, in this embodiment, the solder structures 140 disposed between the insulating thermal substrate 110 and the heat-dissipation component 130 are made of the sintering silver for better matching the corresponding engaging structures 122 (also located therebetween), such that crack resistance of the solder structures 140 can be significantly enhanced. Thereupon, the aforesaid self-cracking problem at the solders between the insulating thermal substrate 110 and the heat-dissipation component 130, caused by relative low thermal conductivity of the solders, can be resolved to avoid possible cracking at the solders and the difficulty in heat transfer therefrom.

In this embodiment, a plurality of intervals GA exists between the insulating thermal substrate 110 and the heat-dissipation component 130. Each of the intervals GA is defined by two neighboring solder structures 140 and the corresponding engaging structure 122. Even upon after the solder structures 140 are squeezed to expand outward by the corresponding engaging structure 122, the interval GA (also regarded as voids or cavities) still exists between the two solder structures 140, as shown in FIG. 1. Actually, these intervals GA provide rooms for the solder structures 140 to thermally expand and be forcedly squeezed without contacting each other. Thereupon, thermal cracking at the solder structures 140 due to different expansion rates of nearby materials would be substantially reduced.

In addition, in an exemplary example, the semiconductor device 100 can be a power module, in which one surface of the insulating thermal substrate 110 (for example, a ceramic circuit board) mounts the heat-dissipation component 130, while the opposing surface of the same insulating thermal substrate 110 mounts at least the power transistor. As a typical power module referring to FIG. 1, besides the power transistor, the thickness D1 of the heat-dissipation component 130 is ranging from 3 mm˜5 mm, the thickness D2 of the solder structures 140 is ranging from 0.15 mm˜0.25 mm, the thickness D3 of the metal wiring layer 120 is ranging from 0.1 mm˜0.2 mm, and the thickness D4 of the insulating thermal substrate 110 is ranging from 0.5 mm˜0.7 mm.

In this embodiment, the metal wiring layer 120 can be formed on the surface 112 of the insulating thermal substrate 110 completely by etching. In detail, a metal layer with a thickness D3 can be firstly deposited or coated onto the surface 112 of the insulating thermal substrate 110, and then the metal layer on the surface 112 of the metal wiring layer 120 is purposely and completely etched so as to obtain thereof a plurality of engaging structures 122 protrusive over the surface 112 of the insulating thermal substrate 110 with a height equal to the thickness D3. However, in this disclosure, methods for manufacturing the engaging structures 122 may be various, but not limited to the aforesaid method. In another embodiment shown in FIG. 1B, the semiconductor device 200 resembling largely to the semiconductor device 100 of FIG. 1A is provided schematically. In these two embodiments of the semiconductor device, the common elements would be assigned by the same numbers, and details thereto would be omitted herein. A major difference between the semiconductor device 200 of FIG. 1B and that 100 of FIG. 1A is that, in this embodiment 200, a metal wiring layer 220 with a thickness D3 deposited or coated on the surface 112 of the insulating thermal substrate 110. The metal wiring layer 220 is not etched all the way to expose the surface 112, but instead the etching at the metal wiring layer 220 is only to produce a plurality of engaging structures 222 with a thickness D5 less than the thickness D3, and thus a base layer 224 as an un-etched portion of the metal wiring layer 220 is left for standing the plurality of engaging structures 222. Namely, the thickness D5, which is also equivalent to an etching depth, is equal to the height of the engaging structures 222.

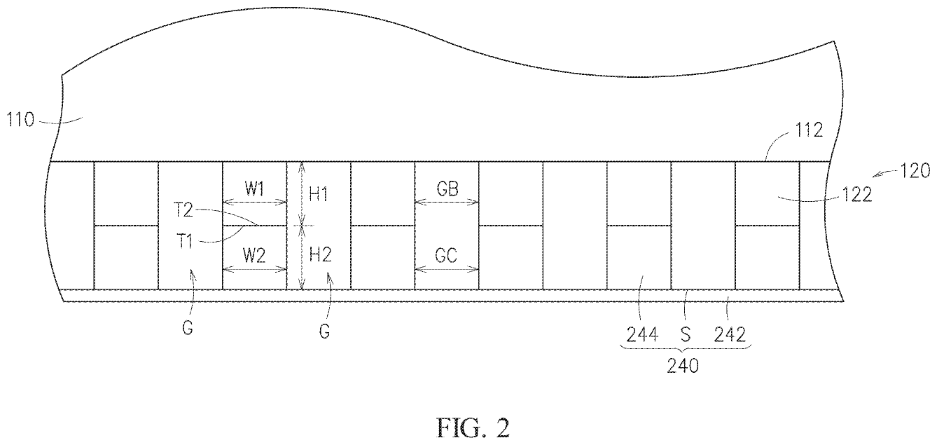

Referring to FIG. 2, a schematic view showing a pre-engaged state of the solder structures and the metal wiring layer in accordance with this disclosure is shown. In this stage, the plurality of the solder structures 240 prior to the engagement with the corresponding engaging structures 122 includes a common planar base 242 and a plurality of protrusive columns 244. Each of the plurality of protrusive columns 244 is protrusive over a surface S of the planar base 242. In other words, the entire solder structures 240 are not presented as a planar surface. In this embodiment, a screen printing process can be applied to print directly the protrusive columns 244 on the surface S of the planar base 242, and the planar base 242 could be a plate solder layer. In some other embodiments, the solder structures 240 can be also made by firstly coating a solder layer on the heat-dissipation component 130 (referring to FIG. 1A or FIG. 1B), and then being etched to form the plurality of protrusive columns 244 and the common planar base 242.

In this embodiment of FIG. 2, the plurality of protrusive columns 244 of the solder structures 240 is arranged in coherence with the engaging structures 122 of the metal wiring layer 120, so that each of the protrusive columns 244 can be aligned with the corresponding engaging structure 122. In particular, these engaging structures 122 can be evenly distributed on the surface 112 of the insulating thermal substrate 110 in a manner. In the manner, each of the engaging structures 122 is spaced to any neighboring engaging structure 122 by a distance, which is equivalent to the first interval GB. That is, the engaging structures 122 can be separated by forming crossing trenches (by previous etching) on the surface 112 with a trench width equal to the first interval GB. On the other hand, the protrusive columns 244 are distributed over the surface S of the planar base 242 in the same manner so as to account for the corresponding engaging structures 122. As shown in FIG. 2, a second interval GC (or the trench width of the crossing trenches for forming the protrusive columns 244) is predetermined to space the neighboring protrusive columns 244. In this embodiment, both the first interval GB and the second interval GC may have, but not limited to, a dimension about 0.5 mm. In some other embodiments, though these engaging structures 122 and the paired protrusive columns 244 may be arranged irregularly or unevenly, but the engaging structures 122 and the paired protrusive columns 244 are still aligned with each other. Thereupon, intervals for separating the neighboring engaging structures 122 or the neighboring protrusive columns 244 would be variable. In addition, a shape of the cross section for the engaging structures 122 can be a polygon, a circle, an ellipse, or the like. In particular, if the shape is a polygon, then it can be a rectangle, a pentagon, an oval, or the like. Similarly, the protrusive column 244 can be relevantly shaped to meet the corresponding engaging structure 122.

In this embodiment, prior to a hot pressing process upon the heat-dissipation component 130 and the insulating thermal substrate 110, the engaging structures 122 of the metal wiring layer 120 are firstly aligned with the corresponding protrusive columns 244 of the solder structures 240, so that a top surface T1 of each of the engaging structures 122 can match a top surface T2 of the corresponding protrusive column 244. At this time, each first interval GB would be aligned and connected spatially with one corresponding second interval GC so as to form the interval G. That is, the protrusive columns 244 are aligned with the engaging structures 122, and the first interval GB is aligned with the second interval GC respectively. Thereupon, between two neighboring protrusive columns 244 and the corresponding engaging structure 122 would be spaced by the interval G, as shown in FIG. 2.

In this embodiment, the top surface T1 of the engaging structure 122 has a width W1, the engaging structure 122 has a height H1 (i.e., equal to the thickness D3 of the metal wiring layer 120 in FIG. 1A), the top surface T2 of the protrusive column 244 has a width W2, and the protrusive column 244 has a height H2. According to this disclosure, a relationship between the engaging structure 122 and the protrusive column 244 of this embodiment can be expressed by the following mathematical equations (1) and (2):

H1≥H2 (1); and

W1≥W2 (2).

Namely, prior to the hot pressing process, the width W1 of the top surface of the engaging structure 122 is greater than or equal to the width W2 of the top surface of the corresponding protrusive column 244, and the height H1 of the engaging structure 122 is greater than or equal to the height H2 of the corresponding protrusive column 244.

In addition, the engaging structure 122 is made of a metal material that is hard to deform at high temperature and high pressure. On the other hand, the solder structures 240 are made of solder that can be heated to a molten state easily deformed by a pressure, and cooled to a solid state to keep the deformation. Thereupon, according to this disclosure, by providing different material properties with respect to changes in temperature and pressure to the engaging structures 122 and the solder structures 240 as described above, the engagement between the engaging structures 122 and the corresponding solder structures 240 can be easily achieved through a relevant temperature operation associated by a simultaneous pressing manipulation. Namely, at a specific high temperature to combine the insulating thermal substrate 110 and the heat-dissipation component 130 with specific forcing, the molten protrusive columns 244 (or the entire solder structures 240) would be deformed upon receiving the corresponding un-deformed engaging structures 122. Then, after the combination of the insulating thermal substrate 110 and the heat-dissipation component 130 is cooled down, the deformation and the contact relationship between the engaging structures 122 and the corresponding solder structures 240 would be stably kept. In one embodiment, the engaging structure 122 can be made of a copper or a copper alloy, and the solder structures 240 can be made of a sintering silver.

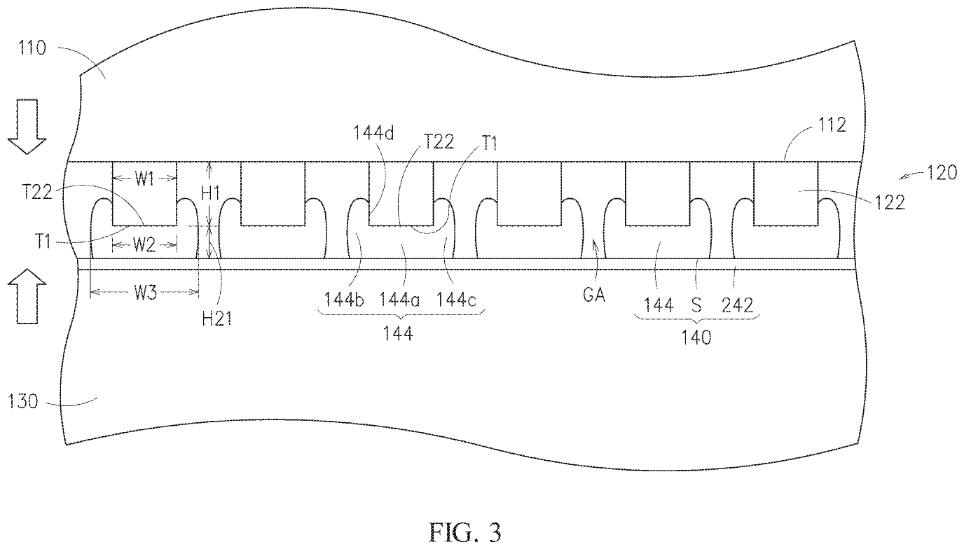

For example, in a typical hot pressing process upon the insulating thermal substrate 110 and the heat-dissipation component 130, the protrusive columns 244 are firstly aligned with the corresponding engaging structures 122. Then, the protrusive columns 244 would be softened and deformed to expand after being heated to a specific high temperature and then being pressed by the approaching engaging structures 122 as well as the insulating thermal substrate 110. At this time, the intervals G provide enough rooms for the molten protrusive columns 244 to expand and deform without contacting each other. Since the protrusive columns 244, squeezed to deform by the invading engaging structures 122, are free to move toward the neighboring intervals G, thus internal stresses of the protrusive column 244 (which cause cracks in some design) would be substantially reduced to minimize the possibility of cracking. Referred to FIG. 3, engagement of the solder structures 140 and the metal wiring layer 120 after the hot pressing process is schematically shown. It is obvious that the protrusive columns 244 of FIG. 2 are heated and squeezed to expand sideward, the top surfaces T2 of the individual protrusive columns 244 are deformed by the forcing from the invading engaging structures 122, and then the squeezed protrusive columns 244 would be deformed into corresponding indentation bodies 144 having concave top surfaces as shown in FIG. 3. Namely, after the hot pressing process as described above, the solder structures 140 would be deformed to include a common planar base 242 and a plurality of indentation bodies 144 individually protruding from the surface S of the planar base 242. In more detail, each the indentation body 144 is mainly consisted of a main column 144a, two lateral columns 144b, 144c and a concave surface 144d, in which a top receiving surface T22 of the indentation body 144 as part of the engaging structures 122 is formed to match the top surface T1 of the invading engaging structure 122. In addition, each the protrusive column 244 of FIG. 2 would be squeezed to deform sideward into the neighboring intervals G, so that the indentation body 144 having the lateral columns 144b, 144c to surround the main column 144a as shown in FIG. 3 would be formed conformally to hold, by partly wrapping, the invading engaging structure 122. In this embodiment, part (i.e., the top portion) of the engaging structure 122 is wrapped by the indentation body 144, while another part thereof is exposed to the neighboring intervals GA.

Referring back to FIG. 2, the height H1 of the engaging structure 122 measuring from the top surface T1 to the surface 112 is greater than or equal to another height H2 of the corresponding protrusive column 244 measuring from the top surface T2 to the surface S. On the other hand, in this embodiment shown in FIG. 3, the height H21 of the indentation body 144 is smaller than H2. Namely, the height H1 of the engaging structures 122 would be greater than the height H21 of the indentation body 144 measuring from the receiving surface T22 to the surface S. In addition, the width W2 of the receiving surface T22 of the indentation body 144 would be equal to the width of the top surface T1 of the engaging structure 122, and the maximum width W3 of the indentation body 144 would be greater than the width W1 of the engaging structure 122. Relationships among H1, H21, W1, W2 and W3 can be expressed by equations (3), (4) and (5) as follows.

H1>H21 (3);

W1=W2 (4); and,

W3>W1 (5).

Apparently, no matter what the cross section of the protrusive column 244 of FIG. 2 is, the receiving surface T22 of the pressed indentation body 144 would demonstrate a corresponding profile to match the top surface T1 of the engaging structure 122. For example, in the case that the cross section of the engaging structure 122 is a polygon, then the top surface T1 of the engaging structure 122 would be the same polygon, and also the receiving surface T22 of the corresponding protrusive column 244 would be a polygon as well to match the top surface T1 of the engaging structure 122. After the indentation body 144 is pressed and thus deformed by the invading engaging structure 122, matching interface between the indentation body 144 and the engaging structure 122 would be complementarily demonstrated. In other words, the receiving surface T22 of the indentation body 144 would be a polygon to match the top surface T1 of the engaging structure 122. In this embodiment, an interval GA (also regarded as voids or cavities) would exist between every two neighboring pressed indentation bodies 144 so that the indentation bodies 144 can be avoided to contact each other.

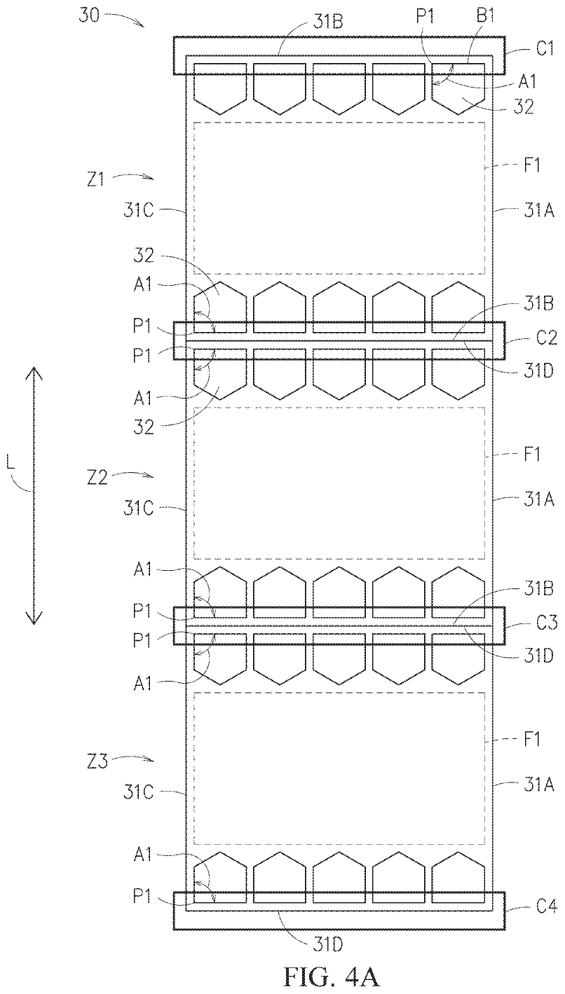

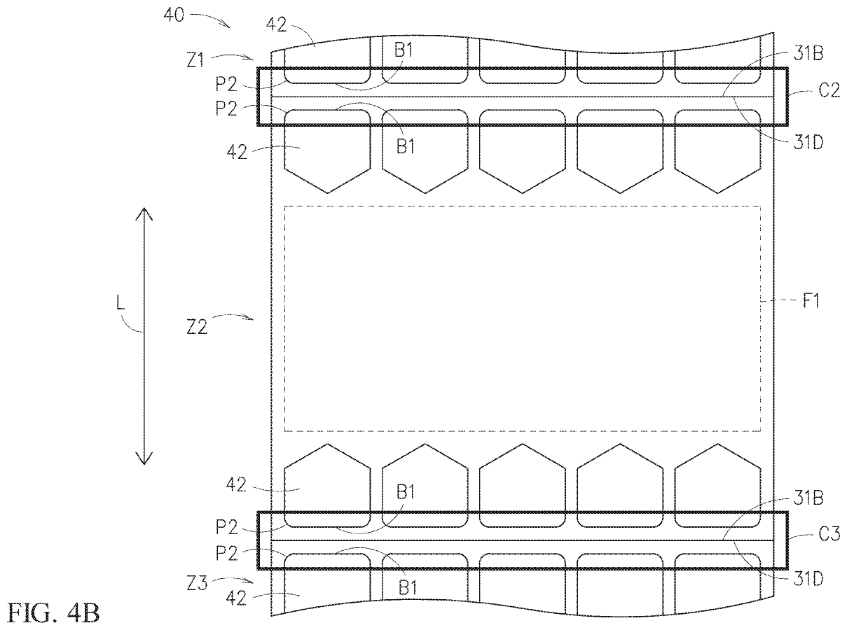

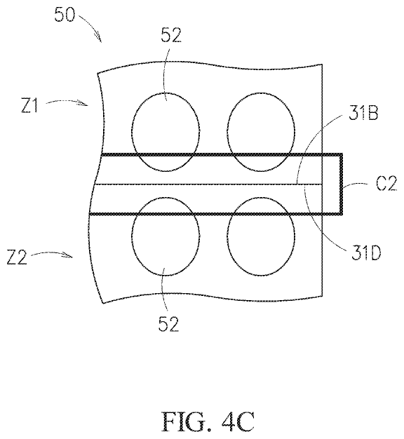

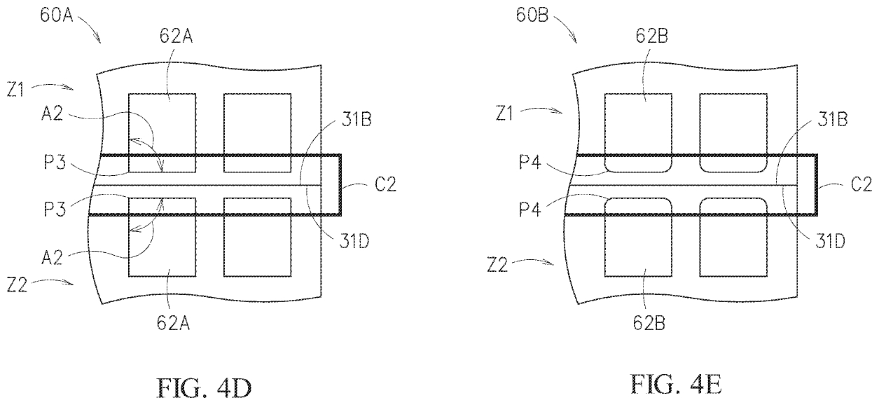

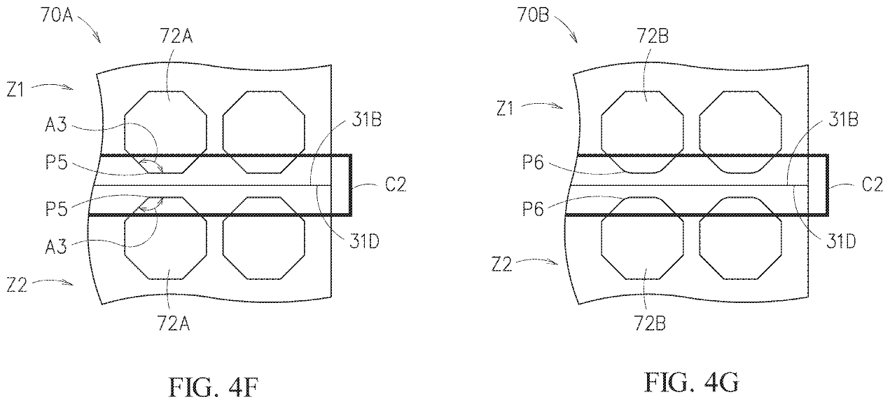

Referring to FIG. 4A, a schematic view of an exemplary example including a plurality of metal wiring layers in accordance with this disclosure is shown. In this example, a metal wiring module 30 includes a first metal wiring layer Z1, a second metal wiring layer Z2, a third metal wiring layer Z3 and a plurality of engaging structures 32. Each of the metal wiring layers Z1-Z3 includes a first edge 31A, a second edge 31B, a third edge 31C and a fourth edge 31D to define a plane, in which the first edge 31A and the third edge 31C are opposite edges, while the second edge 31B and the fourth edge 31D are another opposite edges. The plane of each of the metal wiring layers Z1-Z3 can be the surface 112 of the insulating thermal substrate 110 of FIG. 1A or FIG. 3, or can be the base layer 224 and the engaging structures 222 of the metal wiring layer 22 of FIG. 1B. Namely, the metal wiring module 30 of FIG. 4A is applied to be the semiconductor device 100 or 200 of FIG. 1A or FIG. 1B, respectively, for a power module. In one application, the metal wiring module 30 can be applied to an inverter having three power modules. The first metal wiring layer Z1, the second metal wiring layer Z2 and the third metal wiring layer Z3 can be applied individually to respective half-bridge structures of corresponding power modules of the inverter. Also, the metal wiring module 30 can be applied to three different phases (U, V, W phases) of a three-phase inverter. Obviously, for a concise explanation upon the arrangement of the metal wiring layers, power modules and other components are omitted in FIG. 4A.

In this embodiment, the first metal wiring layer Z1, the second metal wiring layer Z2 and the third metal wiring layer Z3 are linearly arranged in a longitudinal direction L, by having the second edges 31B and the fourth edges 31D as two lengthwise lateral sides (co-edge) of the metal wiring module 30. In particular, the fourth edge 31D of the first metal wiring layer Z1 is neighbored in parallel to the second edge 31B of the second metal wiring layer Z2, such that an edge-connecting region C2 integrating the fourth edge 31D of the first metal wiring layer Z1 and the second edge 31B of the second metal wiring layer Z2 is formed. Similarly, the fourth edge 31D of the second metal wiring layer Z2 is neighbored in parallel to the second edge 31B of the third metal wiring layer Z3, such that another edge-connecting region C3 integrating the fourth edge 31D of the second metal wiring layer Z2 and the second edge 31B of the third metal wiring layer Z3 is formed. Similarly, but only partly shown herein, the second edge 31B of the first metal wiring layer Z1 can be integrated with another fourth edge of another metal wiring layer connecting the first metal wiring layer Z1 linearly in the longitudinal direction L so as to form an edge-connecting region C1. Also, the fourth edge 31D of the third metal wiring layer Z3 can be integrated with another second edge of a further metal wiring layer connecting the third metal wiring layer Z3 linearly in the longitudinal direction L so as to form an edge-connecting region C4.

In this embodiment, since the edge-connecting regions C1, C2, C3, C4 generally form stress concentration areas in the metal wiring module 30, so in order to relieve or reduce possible internal stress in the edge-connecting regions C1, C2, C3, C4, an angle A1 of the corresponding corner P1 of the respective engaging structures 32 in the edge-connecting regions C1, C2, C3, C4 can be made to be equal to or greater than 90°, i.e., a right angle or an obtuse angle. As shown in FIG. 4A, in the first metal wiring layer Z1, a plurality of engaging structures 32 is furnished thereon by closing to the second edge 31B and the fourth edge 31D. The engaging structure 32 has a cross section shaped as a pentagon, and a base side of the pentagon is close to the second edge 31B or the fourth edge 31D of the first metal wiring layer Z1. Further, the angle A1 of the corresponding corner P1 of the pentagonal engaging structure 32 is equal to 90°. In addition, an area F1 inside the first metal wiring layer Z1 can be used for constructing the engaging structures 32, and, according to this disclosure, the arrangement and shape for the engaging structures 32 inside the area F1 are not specifically limited, and thus detail structures of the engaging structures inside the area F are not sketched but denoted by a surrounding dashed-line rectangle. Similarly, a plurality of engaging structures 32 is provided to the second edges 31B and the fourth edges 31D of the corresponding second metal wiring layers Z2 and the corresponding third metal wiring layer Z3, wherein the angle A1 of the corresponding corner P1 of the pentagonal engaging structure 32 is equal to 90°.

It shall be explained that, in the aforesaid description, the engaging structure is taken as a typical example. For the solder structures 24 shown in FIG. 2, an arrangement of the protrusive columns 244 of the solder structures 240 can be embodied as that of the aforesaid engaging structures 32 in FIG. 4A. Also, the shape of the protrusive column 244 shall be inherent with that of the engaging structure 32 in FIG. 4A.

In addition, in order to avoid possible stress concentration at sharp edges of the corner P1 of the engaging structure 32 (or the protrusive column 244 of the corresponding solder structure) such as the corner P1 shown in FIG. 4A, a fillet processing can be applied to the corners P1 of the corresponding engaging structures 32 in each of the edge-connecting regions C1, C2, C3, C4 (or to perform a rounding process upon the engaging structures 122 of FIG. 2). For example, in the embodiment shown in FIG. 4B, corners of the engaging structures in FIG. 4A are processed by the fillet processing. It shall be explained that the metal wiring layer 40 of FIG. 4B is largely resembled to the metal wiring module 30 of FIG. 4A, in which the same numbers are assigned to the components having the same functions, and details thereabout would be omitted herein. A major difference between the metal wiring layer 40 of FIG. 4B and the metal wiring module 30 of FIG. 4A is that, in this embodiment of FIG. 4B, the corners P2 of the corresponding engaging structures 42 have been rounded so as to form respective circular arcs thereof. Thereupon, sharp or uneven edges can be corrected by modifying the corners P2 to corresponding arc angles. In the edge-connecting regions C2, C3 of the metal wiring module 40, each of the engaging structures 42 includes two arc corners P2 and three other corners (5 corners in a pentagon), in which all these arc corners P2 are disposed close to the second edges 31B and the fourth edges 31D in the edge-connecting regions C2, C3.

However, according to this disclosure, shapes of the cross sections of the engaging structures 32, 42 in FIG. 4A and FIG. 4B, respectively, are not limited to the aforesaid embodiments. Referring to FIG. 4C through FIG. 4G, variable embodiments of the metal wiring module 50, 60A, 60B, 70A, 70B largely resembled to the metal wiring module 30 of FIG. 4A. In these embodiments, different cross sections of the engaging structures in the edge-connecting region C2 are provided, elements serving the same functions are assigned with the same number, and thus detail about the same elements would be omitted herein. Referring to FIG. 4C for example, a difference between the metal wiring module 50 of this embodiment and the metal wiring module 30 of FIG. 4A is that, in this embodiment, the cross section for all the engaging structures 52 is an ellipse having no sharp point. In other words, the application of the elliptic cross section can reduce the stress at the edge-connecting region C2.

Referring to FIG. 4D, a difference between the metal wiring module 60A of this embodiment and that 30 of FIG. 4A is that, in this embodiment, the engaging structure 62A has a cross section shaped as a quadrilateral such as a rectangle or a square, and the engaging structure 62A located inside the edge-connecting region C2 would have a corner P3 formed to be a right angle A2, so that he stress in the edge-connecting region C2 can be reduced.

In the embodiment shown in FIG. 4E, stress concentration at the corners would be further reduced. As shown in FIG. 4D, the corners P3 of the engaging structures 62A are sharp points, and thus fillet processing can be applied to work on the sharp points at the corresponding corners P3 of the respective engaging structures 62 in FIG. 4D. Referring to FIG. 4E, a difference between the metal wiring module 60B of this embodiment and the metal wiring module 60A of FIG. 4D is that, in this embodiment, the corners P4 of the engaging structures 62B have been rounded to present arc shapes for further reducing the stress. Each of the engaging structures 62B includes two arc corners P4 and two right-angle corners, in which the arc corners P4 are disposed close to the second edge 31B and the fourth edge 31D in the edge-connecting region C2.

Referring to FIG. 4F, a difference between the metal wiring module 70A of this embodiment and the metal wiring module 30 of FIG. 4A is that, in this embodiment, the engaging structure 72A has a cross section shaped as an octagon, and the angle A3 of the corner P5 of the engaging structures 72A in the edge-connecting region C2 is an obtuse angle that can reduce the stress in the junction area.

In the embodiment shown in FIG. 4G, stress concentration at the corners of the engaging structures 72A would be further reduced. As shown in FIG. 4F, the corners P5 of the engaging structures 72A are sharp points, and thus fillet processing can be applied to work on the sharp points at the corresponding corners P5 of the respective engaging structures 72A in FIG. 4F. Referring to FIG. 4G, a difference between the metal wiring module 70B of this embodiment and that 70A of FIG. 4E is that, in this embodiment, the corners P6 of the engaging structures 72B have been rounded into corresponding arc angles. In detail, at each of the engaging structures 72B, the two corners to be rounded are the two corners who are closer to the second edge 31B or the fourth edge 31D, while the other six corners are kept the same. Each of the engaging structures 72B includes two arc corners P6 and six normal corners (original obtuse-angle corners of the pentagon), in which the two arc corners P6 are closer to the second edge 31B and the fourth edge 31D in the edge-connecting region C2 than the other six corners.

In Table 1 as follows, events “Example 1” and “Example 2” can be applied to the semiconductor device 100 of FIG. 1A. A difference between “Example 1” and “Example 2” is that “Example 1” adopts the metal wiring module 30 of FIG. 4A and the solder structures relevant to pair the metal wiring module 30, and the corners P1 of the engaging structures 32 in the edge-connecting regions C1, C2, C3, C4 of the metal wiring module 30 are yet to experience the fillet processing; while “Example 2” adopts the metal wiring module 40 of FIG. 4B and the solder structures relevant to pair the metal wiring module 40, and the corners P2 of the engaging structures 42 in the edge-connecting regions C2, C3 of the metal wiring module 40 have been fillet processed. From Table 1, no matter what “Example 1” or “Example 2” is applied, the engagement between the solder structures 140 and the corresponding engaging structures 122 according to this disclosure would induce a stress less than 345 Mpa (the yield strength) upon the insulating thermal substrate 110. Thereupon, the problem of excessive stress on the insulating thermal substrate would be resolved. In addition, in comparison to “Example 1” (upon FIG. 4A for example), “Example 2” (upon FIG. 4B for example) that performs the fillet processing upon the corners of the engaging structures 42 in the metal wiring module 40 can effectively remove sharp points so as to avoid possible damages from stress concentration at the sharp points. Also, in “Example 2”, the strain of solder structures is less than 0.016, and thus the cycle life of the semiconductor device can be substantially prolonged to at least 2500 cycles.

TABLE 1

| | | | Yield |
|---|---|---|---|
| | Example 1 | Example 2 | Strength |
| Stress on | 346~350 Mpa | 340~344 Mpa | 345 Mpa |
| Insulating | | | |
| Thermal Substrate | | | |
| Strain of Solder | 0.0165~0.018 | 0.0159~0.015 | 0.016 |
| Structures | | | |

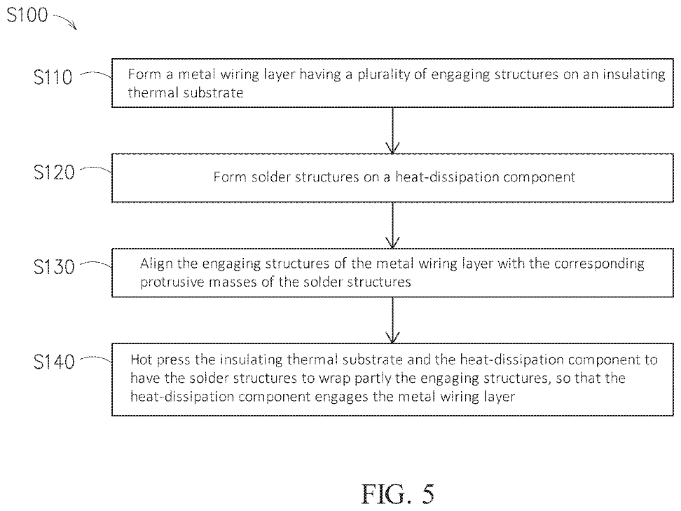

Referring now to FIG. 5, an embodiment of the method for manufacturing a semiconductor device in accordance with this disclosure is shown. This method S100 for manufacturing a semiconductor device can be applied to the semiconductor device 100 of FIG. 1A, or the semiconductor device 200 of FIG. 1B. In this embodiment, the method for manufacturing a semiconductor device S100 includes Step S110 to Step S140 as follows. Firstly, in performing Step S110, a metal wiring layer 120 having a plurality of engaging structures 122 is formed on an insulating thermal substrate 110. In this step, following sub-steps can be performed. Firstly, an insulating thermal substrate 110 is provided, in which the insulating thermal substrate can be made of aluminum nitride, aluminum oxide, beryllium oxide, silicon nitride, or silicon carbide. Then, the metal wiring layer 120 is formed on a surface 112 of the insulating thermal substrate 110 by chemical deposition or physical sputtering. Then, the metal wiring layer 120 is etched to form the engaging structures 122.

In this embodiment, in etching the metal wiring layer 120, a cross section of the engaging structure 122 can be polygonal, round, rectangular, cuboid, heptahedral, octagonal or oval. In particular, while in performing the etch process upon the metal wiring layer 120, the etching can be processed all the way down to the surface 112 of the insulating thermal substrate 110, so that the engaging structures 122 would be formed by directly standing on or protruding from the surface 112 of the insulating thermal substrate 110 (as shown in FIG. 1 A). Alternatively, as shown in FIG. 1B, while in performing the etch process upon the metal wiring layer 120, the etching can be stopped before reaching the surface 112 of the insulating thermal substrate 110. For example, only a thickness D5 is removed from the metal wiring layer 220 having originally a thickness D3 (D3>D5). In this application, the metal wiring layer 220 would be etched to form a common base layer 224 and a plurality of engaging structures 222 protruding from the base layer 224.

In this embodiment, after Step S110 but before Step S120, a fillet processing is applied to at least one corner (corners P1 of the engaging structures 32 in FIG. 4 A, corners P3 of the engaging structures 62A in FIG. 4D, or corners P5 of the engaging structures 72A in FIG. 4F) of the plurality of engaging structures in the edge-connecting regions C1, C2, C3, C4, so as to modify the at least one corner into a corresponding arc corner (corners P2 of the engaging structures 42 in FIG. 4B, corners P4 of the engaging structures 62B in FIG. 4E, or corners P6 of the engaging structures 72B in FIG. 4G). Referring to the exemplary examples shown in FIG. 4A and FIG. 4B, an angle A1 of the corner P1 of the engaging structures 32 in the edge-connecting regions C1, C2, C3, C4 is equal to 90° (as shown in FIG. 4A). Then, the fillet processing is performed upon the corners P1 of the engaging structures 32 (as shown in FIG. 4B).

In this embodiment, in performing the fillet processing upon the corner P1 of the engaging structures 32, scratching can be performed at the corner P1 of the engaging structures 32 so as to modify the corner P1 having sharp points (junction of two adjacent sides for example) into corresponding arc corner (corner P2 for example). Alternatively, in one embodiment, the arc corner (P2 for example) can be produced by direct printing through a screen mold. Further, alternatively, in another embodiment, the arc corner P2 of the engaging structures 42 can be obtained by etching directly the corner P1 of the engaging structures 32. Furthermore, in one embodiment, the arc corner of the engaging structures 42 can be obtained by plating.

Similarly, referring to FIG. 4D and FIG. 4E, the filler processing can be applied to the right-angle corner P3 of the engaging structures 62A in FIG. 4D so as to obtain the corresponding arc corner P4 of the engaging structures 62B in FIG. 4E. Similarly, referring to FIG. 4F and FIG. 4G, the filler processing can be applied to the obtuse-angle corner P5 of the engaging structures 72A in the edge-connecting region C2 of FIG. 4D so as to obtain the corresponding arc corner P6 of the engaging structures 72B in FIG. 4G.

After Step S110, then Step S120 is performed by applying an etching after a screen printing or coating process. Referring to FIG. 2 and FIG. 5, solder structures 240 are firstly formed on a heat-dissipation component 130, in which the solder structures 240 are furnished with a plurality of protrusive columns 244. In this embodiment, a sintering silver is adopted to manufacture the solder structures 240. The sintering silver has a high thermal conductivity to promote heat conduction of the solder structures 240. In addition, Step S120 further includes a sub-step of having an arrangement pattern of the protrusive columns 244 to be coherent with that of the engaging structures 122, such that each of the protrusive columns 244 can match properly one corresponding engaging structure 122.

Referring to FIG. 2, in forming the plurality of protrusive columns 244 from the solder structures 240, a screen printing to provide distribution of the protrusive columns 244 protrusive on the surface S of the planar base 242 can be applied. The shape of the engaging structure defined by the screen printing can be a column having a polygonal, circular, rectangular, quadrilateral (FIG. 4D), pentagonal (FIG. 4A), heptagonal, octagonal (FIG. 4F) or oval (FIG. 4C) cross section. However, this disclosure doesn't provide anyhow a limitation upon the shape of the protrusive column 244. Alternatively, in another embodiment, solder structures 240 are firstly coated on a heat-dissipation component 130. Then, the solder structures 240 are etched to form a plurality of protrusive columns 244 on the planar base 242. In particular, the protrusive column 244 of the solder structures 240 and the engaging structure 122 are coherent in shape.

In another embodiment, the arrangement pattern of the protrusive columns 244 is coherent with that of the corresponding engaging structures 122, such that each of the protrusive columns 244 can match properly the corresponding engaging structure 122 in position. Though the protrusive column 244 is similar in shape to the corresponding engaging structure 122, yet a difference in between is that, in the edge-connecting regions C1, C2, C3, C4, the engaging structure 122 has an arc corner, while the protrusive column 244 is not rounded. Thus, in this embodiment, at least one corner of the protrusive column 244 corresponding to the engaging structure 32 in the edge-connecting regions C1, C2, C3, C4 can be free from a rounding process. That is, in some embodiments, at least one corner of the protrusive column 244 can be a non-arc corner, while the corresponding engaging structure 32 has at least one arc corner. For example, though the protrusive columns 244 may be pentagonal and arranged similarly to FIG. 4A, yet the engaging structure 32 can adopt the corner P2 shown in FIG. 4B for the engaging structure 42.

In some other embodiments, the arrangement pattern of the protrusive columns 244 is coherent with that of the corresponding engaging structures 122, but the protrusive column 244 has an arc corner. The fillet processing is performed upon at least one corner of the protrusive column 244 corresponding the engaging structure 32 in the edge-connecting regions C1, C2, C3, C4. The fillet processing can be executed by scratching the corner of the protrusive column 244, so that the corner with possible sharp points (junction of two adjacent sides for example) can be modified into an arc corner. Alternatively, in one embodiment, the arc corner can be produced by direct printing through a screen mold. Further, alternatively, in another embodiment, the arc corner of the protrusive column 244 can be obtained by etching directly the corner into the arc corner.

After Step S120, Step S130 is performed. Referring to FIG. 2, the plurality of engaging structures 122 of the metal wiring layer 120 is aligned with the corresponding protrusive columns 244 on the solder structures 240 (attached on the heat-dissipation component 130, in which an interval G is furnished to separate the pair of the protrusive column 244 and the corresponding engaging structure 122 from each other. In particular, the arrangement pattern of the engaging structures 122 is coherent and aligned with that of the protrusive columns 244 of the solder structures 240.

After Step S130, Step S140 is performed. Referring to FIG. 3 and FIG. 5, a hot pressing is applied to combine the insulating thermal substrate 110 and the heat-dissipation component 130. Thereupon, with the protrusive columns 244 of the solder structures 140 to be squeezed, to be deformed and thus to wrap partly the corresponding engaging structures 122 of the metal wiring layer 120, the heat-dissipation component 130 can be thus engaged with the metal wiring layer 120.

In this embodiment, referring to FIG. 2 and FIG. 3, the engaging structure 122 is made of a metal material that is hard to deform at high temperature and high pressure. On the other hand, the solder structures 240 are made of solder that can be heated to a molten state easily deformed by a pressure, and cooled to a solid state to keep the deformation. Thereupon, according to this disclosure, by providing different material properties with respect to changes in temperature and pressure to the engaging structures 122 and the solder structures 240 as described above, the engagement between the engaging structures 122 and the corresponding solder structures 240 can be easily achieved through a relevant temperature operation associated by a simultaneous pressing manipulation. Namely, at a specific high temperature and specific forcing, the molten protrusive columns 244 (or the entire solder structures 240) would be deformed upon receiving the corresponding un-deformed engaging structures 122, so that the top surface T2 of the protrusive column 244 would be squeezed by the corresponding engaging structure 122 into the receiving surface T22 (FIG. 3). Thereby, the deformed protrusive column 244 would result in the indentation body 144, such that the engaging structure 122 would pierce into the indentation body 144 in a complementary manner. Further, in the aforesaid process, the interval G of FIG. 2 can provide enough spacing for the protrusive column 244 to be squeezed to expand and deform without contacting the neighboring protrusive columns 244. After the deformation of the protrusive columns 244, the interval G would be narrowed to the interval GA. Thereupon, possible thermal cracking at the protrusive column 244 can be avoided, connection area between the solder structures 140 and the metal wiring layer 120 can be broader, and both the heat-dissipation area and heat-conduction pathways through the solder structures 140 between the insulating thermal substrate 110 and the heat-dissipation component 130 can be increased.

In addition, referring to FIG. 3, after the combination of the insulating thermal substrate 110 and the heat-dissipation component 130 is cooled down and solidified, the combined structure provided by the aforesaid method can minimize the possibility of cracking in the solder structures 140 which will inevitably lead to downgrade the heat conduction performance. Also, the interval GA can provide rooms for the indentation body 144 to expand thermally and to deform, which will contribute to reduce the cracking in solder structures 140.

In summary, by providing the semiconductor device and the method for fabricating the same in accordance with this disclosure, while in hot-depressing the heat-dissipation component and the insulating thermal substrate, with the cross-section design upon the engaging structures of the metal wiring layer and the solder structures, the molten solder structures can wrap the corresponding engaging structures without inducing residual stress in between, thus both the heat-dissipation area and heat-conduction pathways through the solder structures between the insulating thermal substrate and the heat-dissipation component can be substantially increased.

Further, though a big difference exists in the expansion coefficient between the insulating thermal substrate and the heat-dissipation component, yet the solder structures of this disclosure adopting the sintering silver with high thermal conductivity can promote effectively the heat conduction, and also crack resistance at the solder structures can be substantially enhanced. Therefore, solder cracking caused by the difference in thermal conductivity between the insulating thermal substrate and the heat-dissipation component can be avoided.

In addition, according to this disclosure, with specific geometric design on the solder structures and the pairing engaging structures, while in a hot depressing, the solder structures can be expanded into the neighboring intervals without overflowing and contacting, and thus the crack resistance of the solder structures can be improved. Also, with the increase of connection area between the circuit board and the heat-dissipation component, the heat-dissipation performance can be enhanced, and the performance of the transistors and other electronic components can be thus promoted.

Furthermore, since the stress upon the insulating thermal substrate of this disclosure can be less than the yield strength (345 Mpa), and the strain of the solder structures can be up to 0.016, thus the cycle life of the semiconductor device can be effectively prolonged (more than 2500 cycles for example).

In addition, by providing the fillet processing to modify the corners in this disclosure into corresponding arc corners, sharp points or uneven edges can be eliminated, thus possible edge strain at the solder structures would be reduced, so that symmetricity in the solder structures can be uphold without unexpected stress unbalance.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A semiconductor device, comprising:
an insulating thermal substrate;
a metal wiring layer, including a plurality of engaging structures; and
a heat-dissipation component, wherein the plurality of engaging structures is disposed between the insulating thermal substrate and the heat-dissipation component, and the heat-dissipation component applies solder structures to connect the metal wiring layer by having the solder structures to wrap partly the plurality of engaging structures;
wherein the metal wiring layer further includes an edge-connecting region containing part of the plurality of engaging structures, and at least one arc corner of the plurality of engaging structures is disposed close to an edge of the edge-connecting region.

2. The semiconductor device of claim 1, wherein intervals are included to separate the neighboring solder structures and to separate the neighboring engaging structures.

3. The semiconductor device of claim 1, wherein the solder structures are made of a sintering silver.

4. The semiconductor device of claim 1, wherein the plurality of engaging structures is protruded from a surface of the insulating thermal substrate.

5. The semiconductor device of claim 1, wherein the metal wiring layer further includes a base layer disposed between the plurality of engaging structures and a surface of the insulating thermal substrate, and the plurality of engaging structures is protruded from the base layer.

6. The semiconductor device of claim 1, wherein the solder structures include a planar base and a plurality of indentation bodies, the plurality of indentation body is protruded from a surface of the planar base, and the plurality of engaging structures is pierced into the plurality of indentation body.

7. The semiconductor device of claim 6, wherein each of the plurality of engaging structures has a top surface having a width equal to another width of a receiving surface of corresponding one of the plurality of indentation bodies.

8. The semiconductor device of claim 6, wherein each of the plurality of engaging structures has a height greater than another height of corresponding one of the plurality of indentation bodies.

9. The semiconductor device of claim 6, wherein the largest width of each of the plurality of indentation bodies is greater than a width of corresponding one of the plurality of engaging structures.

10. The semiconductor device of claim 1, wherein each of the plurality of engaging structures has a cross section shaped as a polygon, a circle or an ellipse.

11. The semiconductor device of claim 1, wherein the insulating thermal substrate is a ceramic substrate.

12. The semiconductor device of claim 1, wherein the insulating thermal substrate is made of aluminum nitride, aluminum oxide, beryllium oxide, silicon nitride, or silicon carbide.

13. The semiconductor device of claim 1, wherein the metal wiring layer further includes an edge-connecting region containing part of the plurality of engaging structures, and one of the part of the plurality of engaging structures includes at least one arc corner.

14. The semiconductor device of claim 1, wherein the metal wiring layer further includes an edge-connecting region containing part of the plurality of engaging structures, each of the part of the plurality of engaging structures includes at least one corner and at least one arc corner, and the at least one arc corner is disposed close to an edge of the edge-connecting region.

15. A method for manufacturing a semiconductor device, comprising the steps of:
(a) forming a metal wiring layer having a plurality of engaging structures on an insulating thermal substrate, wherein each of the plurality of engaging structures is protruded from the insulating thermal substrate;
(b) forming solder structures on a heat-dissipation component, wherein the solder structures have a plurality of protrusive columns;
(c) aligning the plurality of engaging structures of the metal wiring layer with the plurality of corresponding protrusive columns of the solder structures, wherein an interval exists between any two neighboring of the plurality of protrusive columns and corresponding one of the plurality of engaging structures; and
(d) hot pressing the insulating thermal substrate and the heat-dissipation component to have the solder structures to wrap partly the plurality of engaging structures, so that the heat-dissipation component engages the metal wiring layer, wherein, after the hot pressing, each of the plurality of protrusive columns deforms sideward into the interval.

16. The method for manufacturing a semiconductor device of claim 15, wherein the step (b) includes a step of forming the plurality of protrusive columns having an arrangement pattern coherent with another arrangement pattern of the plurality of engaging structures.

17. The method for manufacturing a semiconductor device of claim 15, wherein the step (b) includes a step of applying screen printing to form a planar base and the plurality of protrusive columns of the solder structures, wherein the plurality of protrusive columns is protruded from a surface of the planar base.

18. The method for manufacturing a semiconductor device of claim 15, wherein the step (b) includes the steps of:
(b1) coating the solder structures onto the heat-dissipation component; and
(b2) etching the solder structures to form the plurality of protrusive columns.

19. The method for manufacturing a semiconductor device of claim 18, wherein the step (b) includes a step of performing a fillet processing upon at least one corner of the plurality of protrusive columns so as to produce a corresponding arc corner.

20. The method for manufacturing a semiconductor device of claim 15, after the step (a), further including a step of performing a fillet processing upon at least one corner angle of the plurality of engaging structures on an edge-connecting region so as to produce a corresponding arc corner.

21. The method for manufacturing a semiconductor device of claim 15, wherein the step (a) includes the steps of:
(a1) providing an insulating thermal substrate;
(a2) forming the metal wiring layer on a surface of the insulating thermal substrate; and
(a3) etching the metal wiring layer to form the plurality of engaging structures.

22. The method for manufacturing a semiconductor device of claim 21, wherein the step (a3) includes a step of etching the metal wiring layer down to the surface of the insulating thermal substrate so as to have the plurality of engaging structures to protrude from the surface of the insulating thermal substrate.

23. The method for manufacturing a semiconductor device of claim 21, wherein the step (a3) includes a step of etching the metal wiring layer by an etch depth to form the plurality of engaging structures and a base layer, the plurality of engaging structures being protruded from the base layer, wherein the etch depth is smaller than a thickness of the metal wiring layer.
